(19) United States
(12) Patent Application Publication
(10) Pub. No.: US 2009/0291562 A1
(43) Pub. Date: Nov. 26, 2009

(54) HELIUM DESCUMMING

(75) Inventor: Alan Jensen, White Salmon, WA (US)

Correspondence Address: Beyer Law Group LLP, P.O. BOX 1687, Cupertino, CA, 95015-1687, US

(73) Assignee: LAM RESEARCH CORPORATION, Fremont, CA (US)

(21) Appl. No.: 12/124,005

(22) Filed: May 20, 2008

(51) Int. Cl. H01L 21/461; B08B 6/00

(52) U.S. Cl. 438/710; 134/1.2; 156/345.25; 257/E21.483

(57) ABSTRACT

A method for forming semiconductor devices is provided. A wafer with a patterned photoresist mask over the wafer, wherein the patterned photoresist mask has patterned photoresist mask features with scum at bottoms of the photoresist mask features is provided. The scum is removed from the bottoms of the photoresist mask features, comprising: providing a descumming gas consisting essentially of helium and forming the helium into a plasma, which removes the scum.

### BACKGROUND OF THE INVENTION

The present invention relates to the formation of semiconductor devices.

During semiconductor wafer processing, features of the semiconductor device are defined in the wafer using well-known patterning and etching processes. In these processes, a photoresist (PR) material is deposited on the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material. In the case of positive photoresist materials, the exposed regions are removed, and in the case of negative photoresist materials, the unexposed regions are removed.

In some lithography processes, scum is left at the bottom of photoresist features. The scum is believed to be photoresist or a by product of photoresist. The scum may also be some other material that forms at the bottom of the photoresist features during the photolithography process.

### SUMMARY OF THE INVENTION

To achieve the foregoing and in accordance with the purpose of the present invention, a method for forming semiconductor devices is provided. A wafer with a patterned photoresist mask over the wafer, wherein the patterned photoresist mask has patterned photoresist mask features with scum at bottoms of the photoresist mask features is provided. The scum is removed from the bottoms of the photoresist mask features, comprising: providing a descumming gas consisting essentially of helium and forming the helium into a plasma, which removes the scum.

In another manifestation of the invention a method for forming semiconductor devices is provided. A wafer with a patterned photoresist mask over the wafer, wherein the patterned photoresist mask has patterned photoresist mask features with scum at bottoms of the photoresist mask features and with an etch layer disposed between the wafer and the patterned photoresist mask is placed within a process chamber. The scum from the bottoms of the photoresist mask features, comprising flowing a descumming gas consisting essentially of helium into the process chamber, forming the helium into a plasma, which removes the scum, and stopping the flow of the descumming gas. The etch layer is etched, comprising providing an etch gas different from the descumming gas into the process chamber and forming the etch gas into a plasma. The wafer is removed from the process chamber.

In another manifestation of the invention an apparatus for forming features in an etch layer, wherein the etch layer is supported by a wafer and wherein the etch layer is covered by a patterned photoresist mask with mask features, with scum at bottoms of the mask features is provided. A plasma processing chamber is provided, comprising a chamber wall forming a plasma processing chamber enclosure, a substrate support for supporting a wafer within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure. A gas source is in fluid connection with the gas inlet and comprises a helium gas source and an etch gas source. A controller is controllably connected to the gas source and the at least one electrode and comprises at least one processor and computer readable media. The computer readable media comprises computer readable code for removing the scum from the bottoms of the photoresist mask features, comprising computer readable code for flowing a descumming gas consisting essentially of helium from the helium gas source into the process chamber, computer readable code for forming the helium into a plasma, which removes the scum, and computer readable code for stopping the flow of the descumming gas, and computer readable code for etching the etch layer, comprising computer readable code for providing an etch gas different from the descumming gas from the etch gas source into the process chamber and computer readable code for forming the etch gas into a plasma.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of a process that may be used in an embodiment of the invention.

FIGS. 2A-D are schematic cross-sectional views of a stack processed according to an embodiment of the invention.

FIG. 3 is a schematic view of a plasma processing chamber that may be used in practicing the invention.

FIGS. 4A-B illustrate a computer system, which is suitable for implementing a controller used in embodiments of the present invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

During lithography processes to form a patterned photoresist mask with photoresist features, scum is left at the bottom of the photoresist features, which then interferes with subsequent processes used to make semiconductor devices. Such processes might be etching features into an underlying etch layer. Many descumming processes remove or damage the photoresist mask, which may degrade the final product.

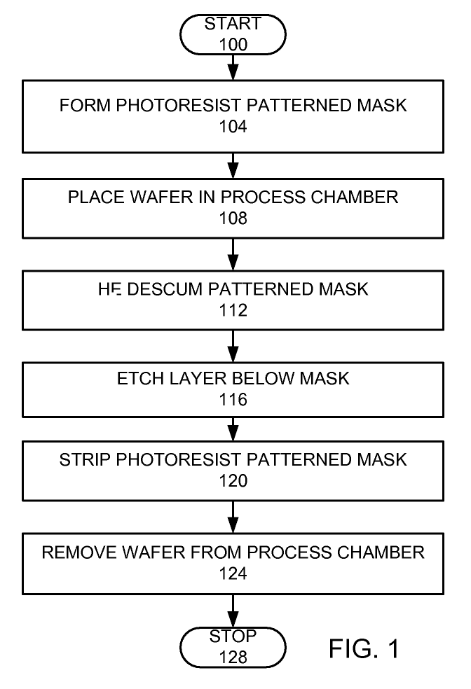

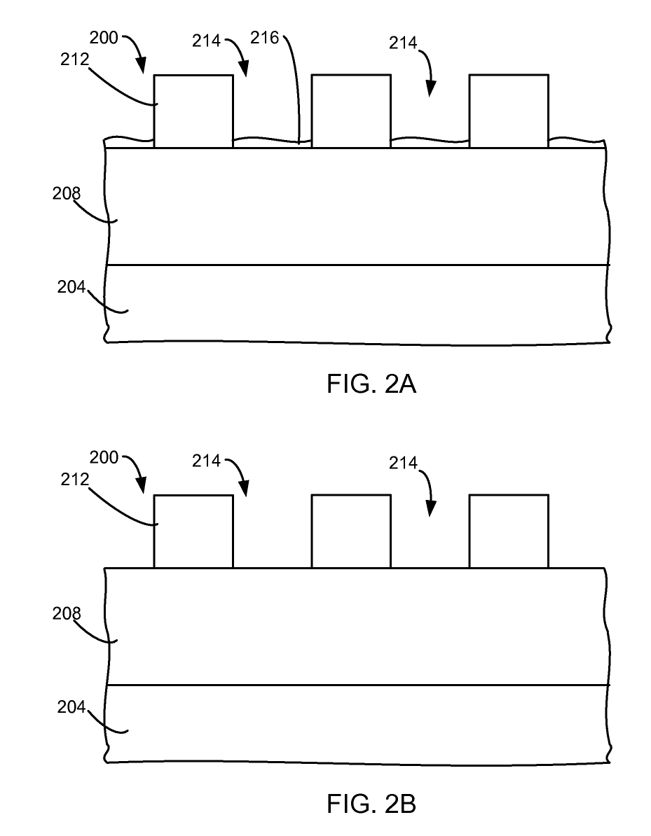

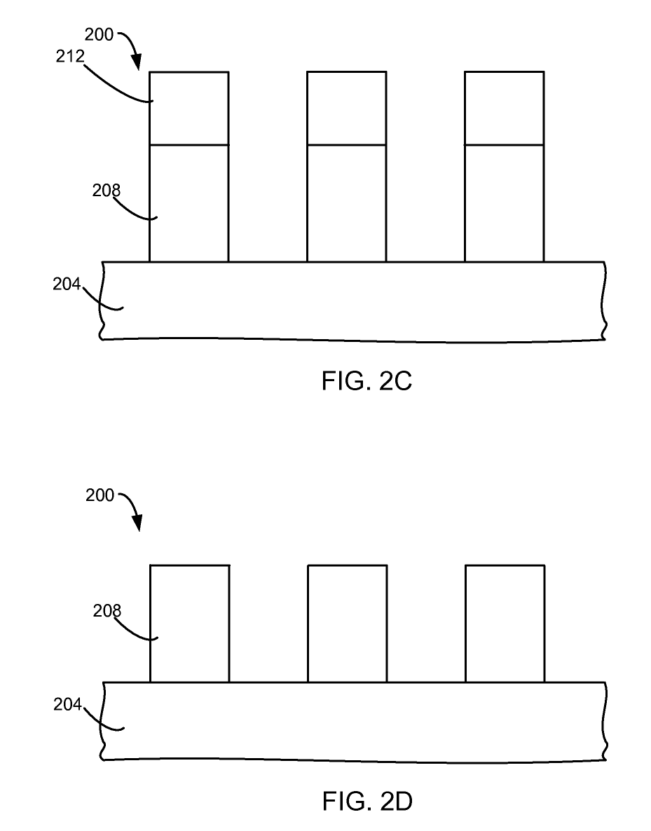

To facilitate understanding, FIG. 1 is a high level flow chart of a process that may be used in an embodiment of the invention. A photoresist patterned mask is formed over a wafer (step 104). FIG. 2A is a schematic cross-sectional view of a stack 200. In this example, an etch layer 208 is formed over the wafer 204. A patterned photoresist mask 212 with mask features 214 is formed over the etch layer 208, which forms a stack 200. An optional BARC (bottom antireflective coating) or ARL (antireflective layer) may be placed between the wafer and the photoresist mask, or the etch layer 208 may be a BARC or ARL and there may be additional layers between the etch layer 208 and the wafer 204. At the bottom of the photoresist features is a layer of scum 216. The scum may be photoresist residue from the lithography process or by products of photoresist or other material that forms at the bottom of the photoresist features during the photolithography process or during subsequent storage or transport of the wafer.

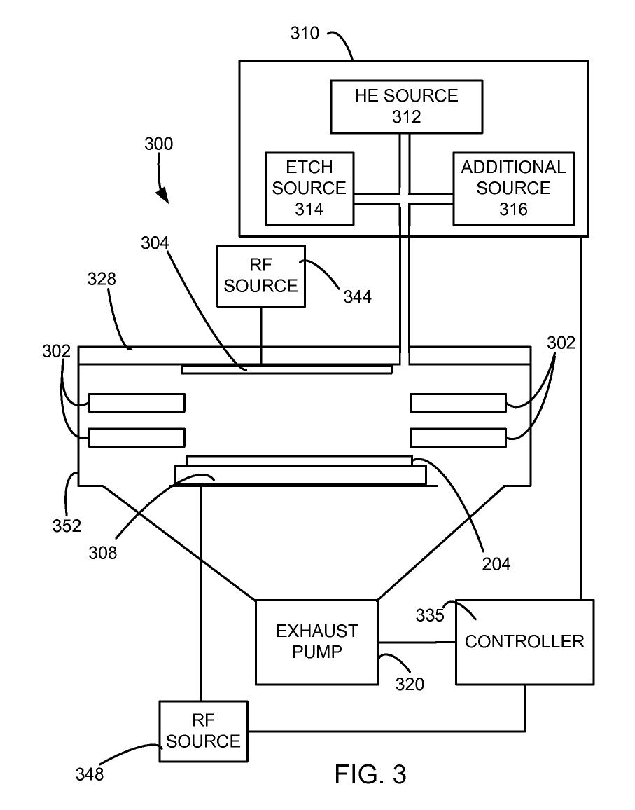

The wafer 204 is placed in a process chamber (step 108). FIG. 3 is a schematic view of a plasma processing chamber 300 that may be used in an embodiment of the invention. The plasma processing chamber 300 comprises confinement rings 302, an upper electrode 304, a lower electrode 308, a gas source 310, and an exhaust pump 320. Within plasma processing chamber 300, the wafer 204 is positioned upon the lower electrode 308. In this embodiment the gas source 310 comprises a helium gas source 312, an etch gas source 314, and an additional source 316. The lower electrode 308 incorporates a suitable substrate chucking mechanism (e.g., electrostatic, mechanical clamping, or the like) for holding the wafer 204. The reactor top 328 incorporates the upper electrode 304 disposed immediately opposite the lower electrode 308. The upper electrode 304, lower electrode 308, and confinement rings 302 define the confined plasma volume. Gas is supplied to the confined plasma volume by the gas source 310 and is exhausted from the confined plasma volume through the confinement rings 302 and an exhaust port by the exhaust pump 320. A first RF source 344 is electrically connected to the upper electrode 304. A second RF source 348 is electrically connected to the lower electrode 308. Chamber walls 352 surround the confinement rings 302, the upper electrode 304, and the lower electrode 308. Both the first RF source 344 and the second RF source 348 may comprise a 60 MHz power source, a 27 MHz power source, and a 2 MHz power source. Different combinations of connecting RF power to the electrode are possible. In the case of Exelan HPT™, which is basically the same as an Exelan HP with a Turbo Pump attached to the chamber, made by LAM Research Corporation™ of Fremont, Calif., which may be used in an embodiment of the invention, the 60 MHz, 27 MHz and 2 MHz power sources make up the second RF power source 348 connected to the lower electrode, and the upper electrode is grounded. A controller 335 is controllably connected to the RF sources 344, 348, exhaust pump 320, and the gas source 310.

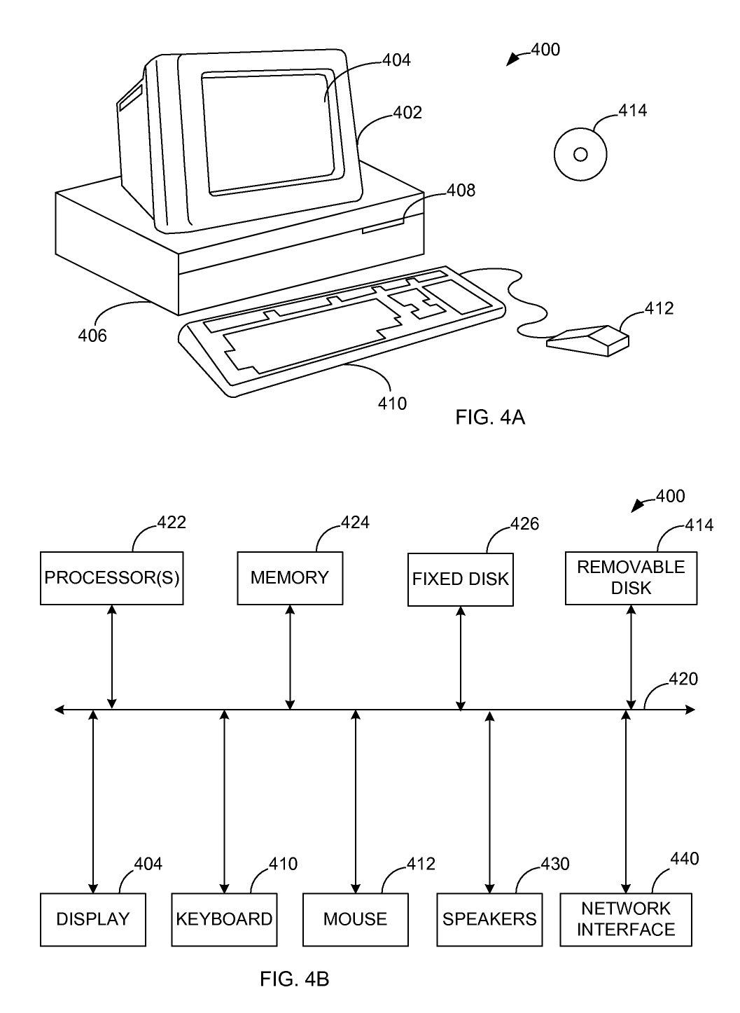

FIGS. 4A and 4B illustrate a computer system 400, which is suitable for implementing a controller 335 used in embodiments of the present invention. FIG. 4A shows one possible physical form of the computer system. Of course, the computer system may have many physical forms ranging from an integrated circuit, a printed circuit board, and a small handheld device up to a huge super computer. Computer system 400 includes a monitor 402, a display 404, a housing 406, a disk drive 408, a keyboard 410, and a mouse 412. Disk 414 is a computer-readable medium used to transfer data to and from computer system 400.

FIG. 4B is an example of a block diagram for computer system 400. Attached to system bus 420 is a wide variety of subsystems. Processor(s) 422 (also referred to as central processing units, or CPUs) are coupled to storage devices, including memory 424. Memory 424 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 426 is also coupled bi-directionally to CPU 422; it provides additional data storage capacity and may also include any of the computer-readable media described below. Fixed disk 426 may be used to store programs, data, and the like and is typically a secondary storage medium (such as a hard disk) that is slower than primary storage. It will be appreciated that the information retained within fixed disk 426 may, in appropriate cases, be incorporated in standard fashion as virtual memory in memory 424. Removable disk 414 may take the form of any of the computer-readable media described below.

CPU 422 is also coupled to a variety of input/output devices, such as display 404, keyboard 410, mouse 412 and speakers 430. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 422 optionally may be coupled to another computer or telecommunications network using network interface 440. With such a network interface, it is contemplated that the CPU might receive information from the network, or might output information to the network in the course of performing the above-described method steps. Furthermore, method embodiments of the present invention may execute solely upon CPU 422 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of tangible computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

A helium descumming of the patterned photoresist mask is performed (step 112). Generally, a descumming gas consisting essentially of helium is provided to the process chamber. The gas in the process chamber, which consists essentially of helium, is formed into a plasma by providing energy from at least one of the RF sources 344, 348 to one of the electrodes 304, 308. Preferably, there is no or low bias. Too much bias will cause the photoresist mask to be sputtered or otherwise damaged, which is undesirable in this embodiment of the invention. FIG. 2B shows the stack 200 after the He descumming process.

An example of a descumming recipe provides a descumming gas of 600 sccm He. A pressure of 200 mtorr is maintained. 500 watt of 60 MHz RF is provided for 30 seconds.

After the descumming process is stopped, the etch layer 208 below the patterned photoresist mask 221 is etched (step 116). In one embodiment, the etch layer is formed by a plurality of layers, which for example is a SiARC (silicon containing antireflective coating) over an organic planarizing layer (spin on photoresist like material), which is over a siliconoxide layer. The etching of the etch layer would first etch the SiARC to transfer the photoresist mask layer. Such a process would provide a SiARC etch gas, which is different than the descumming gas. A plasma is formed by providing energy from at least one of the RF sources 344, 348 through the same electrodes 304, 308, so that the same RF sources and electrodes may be used for both the descumming process and the etching process. The plasma is used to etch SiARC of the etch layer 208. Next the organic planarized layer would be etched, to transfer the pattern to a non-planar surface, using an organic layer etch gas, which is formed into a plasma. The siliconoxide layer is etched by providing a siliconoxide etch gas, which is formed into a plasma. FIG. 2C is a schematic view of the stack 200 after the etch layer 208 is etched.

In another embodiment, one or more layers may be disposed above or below the etch layer, which in this embodiment may be a single layer. For example, the silicon oxide layer may be considered a single layer etch layer. The SiARC and organic planarization layer may be above the etch layer. In such a case, other processes may be performed after the descumming and before etching the etch layer.

If any of the photoresist patterned mask 212 remains after the etch is completed, the photoresist patterned mask 212 may be stripped (step 120) in the process chamber 300, using a conventional stripping process, which may use the same RF sources and electrodes as the descumming process and the etching process. FIG. 2D is a schematic view of the stack 200 after the photoresist mask has been stripped.

The wafer 204 is then removed from the process chamber 300 (step 124).

Without wishing to be bound by theory, the descumming gas consists essentially of helium, since helium is the lightest noble gas. Heavier noble gases, such as argon increase photoresist damage and/or increase CD size. Non-noble gases are believed to react with the photoresist mask, which would etch and excessively damage the photoresist mask. Bias is minimized to minimize photoresist damage. Preferably, the bias voltage is less than 300 volts. More preferably, the bias voltage is less than 150 volts. Most preferably, the bias voltage is less than 115 volts. For example, in the above process chamber, during the descumming, it is preferred that all power is provided at a frequency greater than 50 MHz, which for example is 60 MHz. In this example, no power is provided at 27 MHz and 2 MHz. This embodiment provides the advantage of performing the descumming, etching, and stripping in situ in a single process chamber using the same power source, electrodes, gas inlets, and gas exhaust for all processes.

In another embodiment, during the descumming power may be provided at 27 MHz, where a low pressure is maintained.

In another embodiment, sidewalls are formed on the sides of etch features or photoresist features before or during the etch process. This may be done by forming a polymer layer over sidewalls of the photoresist features or etch features. Such a process may be used to shrink the feature CD's. If formed during the etch process, a single phase process may be used, where the single phase both etches and forms sidewalls. In the alternative, a multiple phase process may be used where one phase deposits sidewalls and another phase etches. Multiple cycles of these phases may be performed. In another embodiment, a shrink layer is formed over the photoresist mask before etching is begun. The He descumming process has been found to improve etches that have a sidewall deposition, especially if the sidewall deposition is used to shrink CD.

The invention may use various embodiments. In another embodiment, the process chamber would provide a down stream plasma for the descumming process. In such an embodiment, a microwave source may generate a plasma, which is then provided to the chamber. In another embodiment, the plasma may be generated in the chamber using a microwave source, so that there is no bias. Such embodiment may perform the etching and stripping in the same chamber or another chamber.

The process chamber in FIG. 3 is a capacitively coupled process chamber. In other embodiments, an inductively coupled process chamber may be used.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for forming semiconductor devices, comprising:
providing a wafer with a patterned photoresist mask over the wafer, wherein the patterned photoresist mask has patterned photoresist mask features with scum at bottoms of the photoresist mask features; and
removing the scum from the bottoms of the photoresist mask features, comprising:
providing a descumming gas consisting essentially of helium; and
forming the helium into a plasma, which removes the scum.

2. The method, as recited in claim 1, where an etch layer is disposed between the wafer and the photoresist mask and further comprising etching the etch layer.

3. The method, as recited in claim 2, further comprising shrinking critical dimensions of the photoresist mask features by forming sidewalls.

4. The method, as recited in claim 3, wherein the descumming, etching, and shrinking are performed in the same chamber.

5. The method, as recited in claim 4, wherein the forming the helium into a plasma provides a bias voltage with a magnitude less than 150 volts.

6. The method, as recited in claim 5, further comprising stripping the patterned photoresist mask, wherein the stripping is performed in the same chamber as the descumming, etching, and shrinking using a same RF electrode.

7. The method, as recited in claim 2, wherein the etching the etch layer forms sidewalls on etch features formed during the etch of the etch layer.

8. The method, as recited in claim 2, wherein the etching the etch layer, comprises a plurality of cycles, wherein each cycle comprises:
a deposition phase for depositing sidewalls; and
an etch phase for etching the etch layer.

9. The method, as recited in claim 2, further comprising depositing a shrink layer on sidewalls of the photoresist mask features of the patterned photoresist mask after the removing the scum and before etching the etch layer.

10. The method, as recited in claim 2, wherein the descumming and etching are performed in the same chamber.

11. The method, as recited in claim 2, further comprising stripping the patterned photoresist mask, wherein the descumming, etching, and stripping are performed in the same chamber using a same RF electrode.

12. The method, as recited in claim 1, wherein the forming the helium into a plasma provides a bias voltage with a magnitude less than 150 volts.

13. The method, as recited in claim 1, wherein the forming the helium into a plasma is performed in a separate chamber than where the wafer is located, wherein the plasma is then flowed to the chamber where the wafer is located as a downstream plasma.

14. A method for forming semiconductor devices, comprising:
placing a wafer with a patterned photoresist mask over the wafer, wherein the patterned photoresist mask has patterned photoresist mask features with scum at bottoms of the photoresist mask features and with an etch layer disposed between the wafer and the patterned photoresist mask within a process chamber;
removing the scum from the bottoms of the photoresist mask features, comprising:
flowing a descumming gas consisting essentially of helium into the process chamber;
forming the helium into a plasma, which removes the scum; and
stopping the flow the descumming gas;
etching the etch layer, comprising:
providing an etch gas different from the descumming gas into the process chamber; and
forming the etch gas into a plasma; and
removing the wafer from the process chamber.

15. The method, as recited in claim 14, further comprising shrinking critical dimensions of the photoresist mask features by forming sidewalls.

16. The method, as recited in claim 14, wherein the forming the helium into a plasma provides a bias voltage with a magnitude less than 150 volts.

17. The method, as recited in claim 14, further comprising stripping the patterned photoresist mask, before removing the wafer from the process chamber.

18. The method, as recited in claim 14, wherein the etching the etch layer forms sidewalls on etch features formed during the etch of the etch layer.

19. An apparatus for forming features in an etch layer, wherein the etch layer is supported by a wafer and wherein the etch layer is covered by a patterned photoresist mask with mask features, with scum at bottoms of the mask features, comprising:
a plasma processing chamber, comprising:
a chamber wall forming a plasma processing chamber enclosure;
a substrate support for supporting a wafer within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising;
a helium gas source; and
an etch gas source
a controller controllably connected to the gas source and the at least one electrode, comprising:
at least one processor; and
computer readable media, comprising:
computer readable code for removing the scum from the bottoms of the photoresist mask features, comprising:
computer readable code for flowing a descumming gas consisting essentially of helium from the helium gas source into the process chamber;
computer readable code for forming the helium into a plasma, which removes the scum; and
computer readable code for stopping the flow the descumming gas; and
computer readable code for etching the etch layer, comprising:
computer readable code for providing an etch gas different from the descumming gas from the etch gas source into the process chamber; and
computer readable code for forming the etch gas into a plasma.
